(19) United States
(12) Patent Application Publication
(10) Pub. No.: US 2022/0052784 A1
(43) Pub. Date: Feb. 17, 2022

(54) DATA PROCESSING IN CHANNEL DECODING

(71) Applicant: NOKIA TECHNOLOGIES OY, Espoo (FI)

(72) Inventors: Kai ZHU, Shanghai (CN); Yu CHEN, Shanghai (CN); Jie CHEN, Naperville, IL (US); Keeth Saliya Jayasinghe LADDU, Piliyandala (LK)

(21) Appl. No.: 17/420,039

(22) PCT Filed: Jan. 14, 2019
(86) PCT No.: PCT/CN2019/071675

§ 371 Date: Jun. 30, 2021

(51) Int. Cl. H04L 1/00; H03M 13/11; H03M 13/13

(52) U.S. Cl. CPC H04L 1/0057; H03M 13/136; H03M 13/1117

(57) ABSTRACT

Embodiments of the present disclosure relate to a device, a method, an apparatus and a computer readable storage medium for data processing. In example embodiments, a method of data processing is provided. The method comprises obtaining, from a channel decoding process, a first input and a second input on which a sum-product operation is to be performed, the sum-product operation including one or more sub-operations. The method further comprises determining a set of mapping relationships for approximating at least one of the one or more sub-operations. The method further comprises determining, based on the first input, the second input and the set of mapping relationships, a first result of the sum-product operation, and continuing the channel decoding process based on the first result. As such, embodiments of the present disclosure can improve error correcting capabilities of Low Density Parity Check (LDPC) code, Polar code, Reed-Muller (RM) code or the like.

### TECHNICAL FIELD

Embodiments of the present disclosure generally relate to data processing, and in particular, to a device, a method, an apparatus and a computer readable storage medium for data processing in channel decoding.

### BACKGROUND

In recent 3GPP specifications (Rel-15), New Radio (NR) enhanced Mobile Broadband (eMBB) standard incorporates two kinds of forward correction codes, i.e. Low Density Parity Check (LDPC) code and Polar code, as the replacement of Long Term Evolution (LTE) Turbo code and tail-biting convolutional code for error correction of data channel and control channel. Similar to the NR eMBB case, LDPC code and Polar code are two strong candidates for NR Ultra Reliable Low Latency Communications (URLLC). URLLC applications impose some unique requirements that differentiate from eMBB, for example, Block Error Rate (BLER) as low as 10⁻⁵, which is more stringent than what has been considered during eMBB standardization. Moreover, the false alarm issue of cyclic redundancy check (CRC) detection merely meets the requirements of eMBB after extending the CRC code to 24 bits. A lower false alarm ratio expected by URLLC is definitely even more challenging.

Therefore, the forward correction codes standardized in Rel-15 have laid good foundation for serving as the baseline. However, the decoding performance of LDPC and/or Polar codes at such a low BLER range needs to be improved so as to meet the requirements of URLLC. Since the operating region of LDPC and/or Polar codes has already been relatively close to the ultimate capacity limit (for example, the performance of Polar-encoded NR Physical Broadcast Channel is only 0.8 dB away from the capacity limit), any kind of performance degradation should not be neglected, especially for URLLC, which targets at ultra-high reliability.

### SUMMARY

In general, example embodiments of the present disclosure provide a device, a method, an apparatus and a computer readable storage medium for data processing in channel decoding.

In a first aspect, there is provided a device for data processing, which comprises at least one processor and at least one memory including computer program code. The at least one memory and the computer program code are configured to, with the at least one processor, cause the device at least to: obtain, from a channel decoding process, a first input and a second input on which a sum-product operation is to be performed, the sum-product operation including one or more sub-operations; determine a set of mapping relationships for approximating at least one of the one or more sub-operations; determine, based on the first input, the second input and the set of mapping relationships, a first result of the sum-product operation performed on the first input and the second input; and continue the channel decoding process based on the first result.

In a second aspect, there is provided a method of data processing. The method comprises obtaining, from a channel decoding process, a first input and a second input on which a sum-product operation is to be performed, the sum-product operation including one or more sub-operations. The method further comprises determining a set of mapping relationships for approximating at least one of the one or more sub-operations. The method further comprises determining, based on the first input, the second input and the set of mapping relationships, a first result of the sum-product operation performed on the first input and the second input. In addition, the method further comprises continuing the channel decoding process based on the first result.

In a third aspect, there is provided an apparatus comprising means to perform the method according to the second aspect.

In a fourth aspect, there is provided a computer readable storage medium that stores a computer program thereon. The computer program, when executed by a processor of a device, causes the device to perform the method according to the second aspect.

It is to be understood that the summary section is not intended to identify key or essential features of embodiments of the present disclosure, nor is it intended to be used to limit the scope of the present disclosure. Other features of the present disclosure will become easily comprehensible through the following description.

### BRIEF DESCRIPTION OF THE DRAWINGS

Through the more detailed description of some embodiments of the present disclosure in the accompanying drawings, the above and other objects, features and advantages of the present disclosure will become more apparent, wherein:

FIGS. 1A and 1B illustrates schematic diagrams of an example communication system 100 in which embodiments of the present disclosure can be implemented;

FIG. 2 is a flowchart of an example method for data processing according to some embodiments of the present disclosure;

FIG. 3 illustrates a schematic diagram of performance comparison of three variants of the sum-product operation; and

FIG. 4 is a simplified block diagram of a device that is suitable for implementing embodiments of the present disclosure.

Throughout the drawings, the same or similar reference numerals represent the same or similar element.

### DETAILED DESCRIPTION

Principle of the present disclosure will now be described with reference to some example embodiments. It is to be understood that these embodiments are described only for the purpose of illustration and help those skilled in the art to understand and implement the present disclosure, without suggesting any limitation as to the scope of the disclosure. The disclosure described herein can be implemented in various manners other than the ones described below.

In the following description and claims, unless defined otherwise, all technical and scientific terms used herein have the same meaning as commonly understood by one of ordinary skills in the art to which this disclosure belongs.

As used herein, the term “communication network” refers to a network that follows any suitable communication standards or protocols such as long term evolution (LTE), LTE-Advanced (LTE-A) and the fifth generation (5G) New Radio (NR), and employs any suitable communication technologies, including, for example, Multiple-Input Multiple-Output (MIMO), OFDM, time division multiplexing (TDM), frequency division multiplexing (FDM), code division multiplexing (CDM), Bluetooth, ZigBee, machine type communication (MTC), eMBB, mMTC and uRLLC technologies. For the purpose of discussion, in some embodiments, the LTE network, the LTE-A network, the 5G NR network or any combination thereof is taken as an example of the communication network.

As used herein, the term “network device” refers to any suitable device at a network side of a communication network. The network device may include any suitable device in an access network of the communication network, for example, including a base station (BS), a relay, an access point (AP), a node B (NodeB or NB), an evolved NodeB (eNodeB or eNB), a gigabit NodeB (gNB), a Remote Radio Module (RRU), a radio header (RH), a remote radio head (RRH), a low power node such as a femto, a pico, and the like. For the purpose of discussion, in some embodiments, the eNB is taken as an example of the network device.

The network device may also include any suitable device in a core network, for example, including multi-standard radio (MSR) radio equipment such as MSR BSs, network controllers such as radio network controllers (RNCs) or base station controllers (BSCs), Multi-cell/multicast Coordination Entities (MCEs), Mobile Switching Centers (MSCs) and MMEs, Operation and Management (O&M) nodes, Operation Support System (OSS) nodes, Self-Organization Network (SON) nodes, positioning nodes, such as Enhanced Serving Mobile Location Centers (E-SMLCs), and/or Mobile Data Terminals (MDTs).

As used herein, the term “terminal device” refers to a device capable of, configured for, arranged for, and/or operable for communications with a network device or a further terminal device in a communication network. The communications may involve transmitting and/or receiving wireless signals using electromagnetic signals, radio waves, infrared signals, and/or other types of signals suitable for conveying information over air. In some embodiments, the terminal device may be configured to transmit and/or receive information without direct human interaction. For example, the terminal device may transmit information to the network device on predetermined schedules, when triggered by an internal or external event, or in response to requests from the network side.

Examples of the terminal device include, but are not limited to, user equipment (UE) such as smart phones, wireless-enabled tablet computers, laptop-embedded equipment (LEE), laptop-mounted equipment (LME), and/or wireless customer-premises equipment (CPE). For the purpose of discussion, in the following, some embodiments will be described with reference to UEs as examples of the terminal devices, and the terms “terminal device” and “user equipment” (UE) may be used interchangeably in the context of the present disclosure.

As used herein, the term “cell” refers to an area covered by radio signals transmitted by a network device. The terminal device within the cell may be served by the network device and access the communication network via the network device.

As used herein, the term “circuitry” may refer to one or more or all of the following:

(a) hardware-only circuit implementations (such as implementations in only analog and/or digital circuitry) and
(b) combinations of hardware circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions) and
(c) hardware circuit(s) and or processor(s), such as a microprocessor(s) or a portion of a microprocessor(s), that requires software (e.g., firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

As used herein, the singular forms “a”, “an”, and “the” are intended to include the plural forms as well, unless the context clearly indicates otherwise. The term “includes” and its variants are to be read as open terms that mean “includes, but is not limited to”. The term “based on” is to be read as “based at least in part on”. The term “one embodiment” and “an embodiment” are to be read as “at least one embodiment”. The term “another embodiment” is to be read as “at least one other embodiment”. Other definitions, explicit and implicit, may be included below.

As described above, in order to improve system performance and enhance user experience, some personal information of an end user (for example, user name, password, age, gender, fingerprints, telephone number, unique device identifier, location, credit card number, financial record, medical record and the like) may be collected, stored, used, maintained and/or disseminated by service providers with the authorization of the end user. However, some service providers may collect personal information which is not related to the provided services, in order to do data mining and analysis in depth to enable other services for getting more profits. Moreover, some service providers may share the collected personal information with third parties without informing related end users. All of these might threaten privacy of the end users.

As described above, the error correcting capabilities of LDPC and/or Polar codes need further improvements in order to fulfil the requirements of URLLC. Owing to practical considerations, it is common that modern decoding algorithms are implemented in log-domain to avoid numerical overflow and/or underflow. A few examples have already been deployed in commercial services, such as BCJR for Turbo code, belief propagation for LDPC code as well as successive cancellation for Reed-Muller (RM) code, the said decoding operations are all performed in log-domain. Another advantage that could be beneficial in practice is that arithmetical operations become fairly easy when transferring the decoding algorithms from linear domain to log-domain. For instance, a multiplication operation in linear domain now becomes an additive operation, which is undoubtedly easier to be implemented.

As a result, a Likelihood Ratio (LR, which refers to a probability ratio of one given bit is 1 against it is 0 or the other way around) is usually converted to log-domain and the resultant is generally termed as Log-Likelihood Ratio (LLR). In fact, LLR calculation plays a critical role in modern soft-information based decoding algorithms. Generally speaking, the use of LLR makes decoding easier and faster than LR in most circumstances. Unfortunately, for several special arithmetical operations, log-domain calculations might yield prohibitively-high complexity, for example, Jacobian logarithm and sum-product operation.

As a compromise, traditional solutions usually incorporate a sub-optimal alternative in order to approximate the original Jacobian logarithm and sum-product operation. Such sub-optimal replacement may be inaccurate and inevitably lead to degraded performance due to improper approximation.

Assuming that A and B are two inputs of a sum-product operation, the sum-product operation performs the following operation in the log-domain:

$$f = ln \frac{1 + exp ( A + B )}{exp ( A ) + exp ( B )} = s i g n ( A ) s i g n ( B ) min ( \vert A \vert , \vert B \vert ) + ln ( 1 + exp ( - \vert A + B \vert ) ) - ln ( 1 + exp ( - \vert A - B \vert ) ) \qquad ( 1 )$$

Some traditional solutions tend to consider the first term only (that is, sign(A)sign(B) min(|A|, |B|), this simplified version of sum-product being generally termed as min-sum), while the second and third terms as following are ignored:

g=ln(1+exp(−|A+B|))−ln(1+exp(−|A−B|)) (2)

Simplification of this fundamental inherently brings numerical inaccuracy leading to inevitable performance degradation.

Numerous evidences can approve that the error correction capabilities are degraded remarkably for LDPC when using the simplified sum-product (such as, min-sum) during decoding. Furthermore, it is shown that performance gap is further deteriorated when the transmission block size is getting larger and/or the coding rate is becoming lower, such as ⅓ and ⅕, which are important rate regions for NR URLLC services. In worst case scenario, such degradation may be exaggerated up to 0.5 dB or more.

It is to be understood that the sum-product operation is a critical component of both LDPC and/or Polar decoders. In particular, the sum-product operation is performed during the check node update in LDPC decoding, whilst f-node calculation in Polar decoding.

Some traditional solutions attempt to improve the error correction capabilities in the context of LDPC decoding by offsetting, normalizing or adjusting the min-sum (that is, sign(A)sign(B) min(|A|, |B|). However, some of these traditional solutions may be based on incorrect understanding of the sum-product, and thus cannot offer the best approximation to the true value of sum-product. Additionally, some of these traditional solutions may introduce extra latency and/or complexity, and thus may be difficult to be implemented in practice. Moreover, some of these traditional solutions may have a requirement on the number of iterations, and thus may be incapable of bringing noticeable benefit with a small number of iterations. In addition, some of these traditional solutions may depend on the iterative structure of LDPC decoder, and thus may be inapplicable to decoders with other structures.

Embodiments of the present disclosure propose a solution for data processing in channel decoding, so as to solve the problem above and one or more of other potential problems. This solution can greatly improve the error correcting capabilities of LDPC and/or Polar codes, while offering a good balance between performance improvement and implementation complexity. This solution directly compensates the less significant term of the equation (1) instead of relying on decoder structures, and thus it can work well with both iterative and successive decoding algorithms. It is to be understood that this solution is not tailored for LDPC or Polar codes. Rather, it can be incorporated in a LDPC decoder, a Polar and/or RM decoder or other decoders with minimum modification.

For the purpose of illustration, in the following, embodiments of the present disclosure will be described in the context of channel decoding (such as, LDPC, Polar and/or RM decoding). However, it is to be understood that the sum-product operation as shown in the above equation (1) is widely used in many fields, such as, physics, hydromechanics, and the like. Therefore, embodiments of the present disclosure are also applicable to these fields, and the scope of the present disclosure is not limited in this regard.

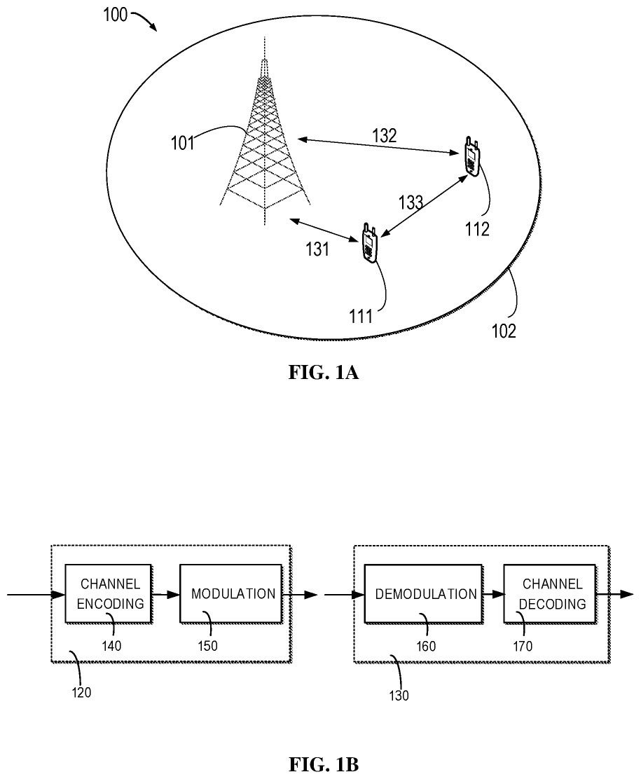

FIG. 1A is a diagram illustrating an example wireless communication system 100 in which embodiments of the present disclosure can be implemented. The wireless communication system 100 may include a network device 101 and a plurality of terminal devices 111 and 112 served by the network device 101. The network 100 may provide one or more serving cells 102 to serve the terminal devices 111 and 112. The terminal devices 111 and 112 may communicate with the network device 101 via wireless transmission channels 131 and 132 respectively, and/or may communicate with each other via a wireless transmission channel 133. It is to be understood that the number of network devices, terminal devices and/or serving cells is only for the purpose of illustration without suggesting any limitations to the present disclosure.

FIG. 1B is a simplified diagram illustrating processing implemented at a transmitting device 120 and a receiving device 130 in communication. In some embodiments, the network device 101 may act as the transmitting device 120, while the terminal device 111 or 112 in FIG. 1 may act as the receiving device 130. In some embodiments, the network device 101 may act as the receiving device 130, while the terminal device 111 or 112 in FIG. 1 may act as the transmitting device 120.

As shown in FIG. 1B, in order to ensure reliable transmission of data (including control signaling), the transmitting device 120 may perform channel encoding (140) on the data to be transmitted to introduce redundancy, thereby resisting distortion probably introduced in a transmission channel (for example, 131, 132, and 133 in FIG. 1A). Alternatively, the channel-encoded data may be further interleaved (not shown) and/or modulated (150) before being transmitted. At the receiving device 130, a process reverse to that of the transmitting device 120 is performed. That is, the received signal is demodulated (160), de-interleaved (not shown) and decoded (170) to recover the transmitted data. In some embodiments, other or different processing may be involved at the transmitting device 120, and the receiving device 130 may perform a reverse operation accordingly.

In some embodiments, LDPC, Polar and/or RM codes may be used as error correction codes in the channel encoding process 140 in FIG. 1B. It is to be understood that the channel as used herein refers to an encoding channel, namely a channel involved in the encoding process from an input to an output, rather than the transmission channel 131, 132 or 133 in FIG. 1A. Accordingly, the channel decoding process 170 in FIG. 1B may be used for decoding the received signals including the error correction codes, such as, LDPC, Polar and/or RM codes.

In the modulation process 150 in FIG. 1B, any modulation technique currently known or to be developed in the future may be used, such as Binary Phase Shift Keying (BPSK), π/2-BPSK, Quadrature Phase Shift Keying (QPSK), 16 Quadrature Amplitude Modulation (16QAM), 64QAM and 256QAM. In the modulation process 160 in FIG. 1B, a corresponding demodulation manner will be employed in accordance with the modulation technique used in the modulation process 150.

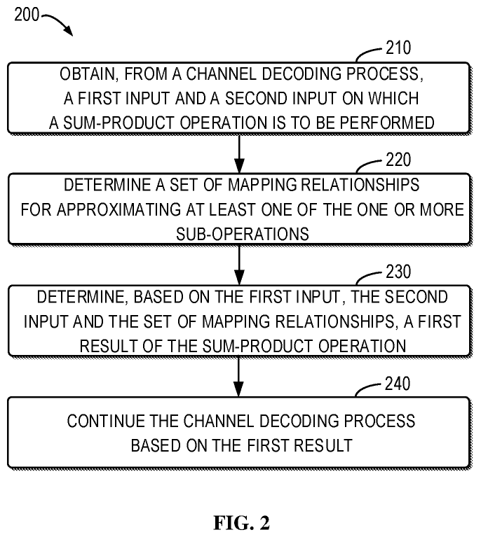

FIG. 2 illustrates a flowchart of a method 200 in accordance with embodiments of the present disclosure. The method 200 may be implemented at the receiving device 130 in the communication network 100. For example, the receiving device 130 may be the terminal device 111 or 112, or the network device 101 as shown in FIG. 1. It is to be understood that method 200 may further include additional blocks not shown and/or omit some shown blocks, and the scope of the present disclosure is not limited in this regard.

As shown in FIG. 2, at block 210, the receiving device 130 obtains, from the channel decoding process 170, a first input and a second input on which a sum-product operation is to be performed.

In some embodiments, the first input may indicate a first ratio between a first likelihood that a first received bit is decoded to a first value and a second likelihood that the first received bit is decoded to a second value. The second input may indicate a second ratio between a third likelihood that a second received bit is decoded to the first value and a fourth likelihood that the second received bit is decoded to the second value. For example, the first value may be 1, while the second value may be 0. As another example, the first value may be 0, and the second value may be 1.

In some embodiments, the first input and the second input are two LLRs obtained from the channel decoding process 170 (for example, generated directly from the soft de-mapper), on which a sum-product is to be performed. For example, assuming that the first input is represented as ‘A’ and the second input is represented as ‘B’, the sum-product operation to be performed on the first and second inputs is defined as the above equation (1). The sum-product operation may include one or more sub-operations, such as two individual Jacobian logarithm operations as shown in the above equation (2).

At block 220, the receiving device 130 determines a set of mapping relationships for approximating at least one of the one or more sub-operations.

The one or more sub-operations as shown in the above equation (2) may be represented as a curve in a 3-Dimensional (3D) space. In some embodiments, the receiving device 130 may determine a set of elementary curves (also referred to as “mapping relationships”) from 2-Dimensional (2D) spaces to approximate the 3D curve. For example, a total of M elementary curves from 2D spaces can be carefully designed in order to accurately approximate the true value of the term g in the above equation (2).

In some embodiments, the value of M can be optionally adjusted so as to suit different requirements of target deployment. In particular, for some scenarios requiring extremely high reliability, a larger value may be chosen. For other scenarios that focus on extremely low latency, a smaller value may be chosen. In some embodiments, for example, M≥1. In some embodiments, for example, M ranges from 4 to 6.

In some embodiments, for example, the set of mapping relationships for approximating the true value of the term g in the above equation (2) can be represented as following:

$$J ( x ) = \{ \begin{matrix}- {S}_{1} * x + {D}_{1} , & x ∈ [ 0 , {K}_{1} ) \\ - {S}_{2} * x + {D}_{2} , & x ∈ [ {K}_{1} , {K}_{2} ) \\ … & … \\ 0 , & x ∈ [ {K}_{n} , + ∞ )\end{matrix} \qquad ( 3 )$$

where the parameters S₁, S₂, . . . Sₙ can be determined based on the value of M. For example, the value of each of the parameters S₁, S₂, . . . Sₙ can take from a series of base-2 exponentials such that it can be easily implemented by bit-level shift. In some embodiments, for example, each of the parameters S₁, S₂, . . . Sₙ ranges from −0.5 to 0. The parameters K₁, K₂, . . . Kₙ can be determined based on the value of M. In some embodiments, for example, each of the parameters K₁, K₂, . . . Kₙ ranges from 0 to 6. The parameters D₁, D₂, . . . Dₙ can be determined based on the value of M. In some embodiments, for example, each of the parameters D₁, D₂, . . . Dₙ ranges from 0 to 1. It is to be understood that the values of the above parameters can be determined and fine-tuned offline to best suit different deployment scenarios instead of requiring on-the-fly adjustment.

In some embodiments, the set of mapping relationships J(x) as shown in the above equation (3) can be stored as a lookup table in a memory. As such, the receiving device 130 may obtain, from the memory, the lookup table representing the set of mapping relationships J(x).

In some embodiments, in order to achieve better accuracy, both the first input A and the second input B need to be taken into account jointly, instead of considering them as separate variables and treating them individually. Typically, it usually requires implementing two or more lookup tables for approximating the 3D curve. The number of lookup tables may be as many as the result of Cartesian product of A and B. By contrast, in the embodiments of the present disclosure, only one lookup table is required due to the joint processing of the first input A and the second input B.

At block 230, the receiving device 130 determines, based on the first input A, the second input B and the set of mapping relationships J(x), a result (also referred to as “first result” in the following) of the sum-product operation performed on the first input and the second input.

In some embodiments, the receiving device 130 may determine, based on the first input A, the second input B and the set of mapping relationships J(x), a result (also referred to as “second result” in the following) of the term g in the above equation (2), and then determine the first result of the sum-product operation (that is, the term f in the above equation (1)).

In some embodiments, in order to determine the second result, the receiving device 130 may determine a first absolute value of a sum of the first input A and the second input B, and determine a first candidate result of the term g in the above equation (2) based on the first absolute value and the set of mapping relationships. The receiving device 130 may determine a second absolute value of a difference between the first input and the second input, and determine a second candidate result of the term g in the above equation (2) based on the second absolute value and the set of mapping relationships. Then, the receiving device 130 may select, by comparing the first absolute value and the second absolute value, one of the first candidate result, the second candidate result and a predetermined value (such as, 0) as the second result.

For example, in order to further reduce the complexity, an additional selector Ψ as shown in the following equation (4) can be used to quickly determine the second result:

$$g \approx Ψ = \{ \begin{matrix}J ( \vert A + B \vert ) , & \vert A + B \vert < C , \vert A - B \vert > C 2 * \vert A + B \vert \\ - J ( \vert A - B \vert ) , & \vert A - B \vert < C , \vert A + B \vert > C 2 * \vert A - B \vert \\ 0 , & otherwise\end{matrix} \qquad ( 4 )$$

where two constants C and C2 determine the polarity of the output. In some embodiments, for example, the constants C and C2 each range from 0.5 to 5.5.

The above equation (3) in conjunction with the above equation (4) can achieve high approximation accuracy of the sum-product operation by utilizing only one lookup table rather than multiple tables. This in turn results in significant improvements for LDPC and/or Polar codes in terms of decoding error rate as will be further discussed in the following. It is to be understood that the principle of the present disclosure can be extended to use 3D curves to approximate a curve in 4-Dimensional space.

Specifically, in the following, examples of the above equations (3) and (4) with recommended parameters are shown in equations (5) and (6) as below:

$$\begin{matrix}J ( x ) = \{ \begin{matrix}- 0.394 * x + 0.680 , & x ∈ [ 0 , 0.881 ) \\ - 0.221 * x + 0.533 , & x ∈ [ 0.881 , 1.665 ) \\ - 0.118 * x + 0.364 , & x ∈ [ 1.665 , 2.403 ) \\ - 0.046 * x + 0.189 , & x ∈ [ 2.403 , 3.821 ) \\ 0 , & x ∈ [ 3.821 , + ∞ )\end{matrix} & ( 5 ) \\ g \approx Ψ = \{ \begin{matrix}J ( \vert A + B \vert ) , & \vert A + B \vert < 4.4 , \vert A - B \vert > 1.5 * \vert A + B \vert \\ - J ( \vert A - B \vert ) , & \vert A - B \vert < 4.4 , \vert A + B \vert > 1.5 * \vert A - B \vert \\ 0 , & otherwise\end{matrix} & ( 6 )\end{matrix}$$

In the above equation (5), S₁=0.394, S₂=0.221, S₃=0.118, S₄=0.046, D₁=0.680, D₂=0.533, D₃=0.364, D₄=0.189, K₁=0.881, K₂=1.665, K₃=2.403 and K₄=3.821. In the above equation (6), C=4.4 and C2=1.5. Let Δ=|Ψ−the true value of g|, the mean of Δ is able to reach as low as 7.5e⁻⁴ and the variance of Δ is in the order of magnitude 1.7e⁻⁵, which demonstrate high approximation accuracy.

At block 240, the receiving device 130 continues the channel decoding process based on the determined result of the sum-product operation performed on the first input and the second input.

In some embodiments, the above method 200 may be applied to Polar decoding. That is, the channel decoding process may be used for decoding of Polar codes. As such, an implementation of the sum-product operation with low complexity can be conceived, which is capable of mitigating the LLR inaccuracy problem in those traditional solutions that only consider min-sum while ignoring operations formulated in the equation (2). The above method 200 can be applied to the most critical decoding steps in Polar decoding, such as, LLR calculations in decoding bits with odd indices (that is, f-node) and/or in decoding bits with even indices (that is, g-node).

For example, in Polar decoding, a recursive formula used for decoding a bit with an odd index (that is, 2i−1) is shown as below:

$$L L {R}_{N}^{2 i - 1} ( {y}_{1}^{N} , {\hat{u}}_{1}^{2 i - 2} ) = ln \frac{1 + exp ( {LLR}_{\frac{N}{2}}^{i} ( {y}_{1}^{\frac{N}{2}} , {\hat{u}}_{1 , o}^{2 i - 2} ⊕ {\hat{u}}_{1 , e}^{2 i - 2} ) + {LLR}_{\frac{N}{2}}^{i} ( {y}_{\frac{N}{2} + 1}^{N} , {\hat{u}}_{1 , e}^{2 i - 2} ) )}{exp ( {LLR}_{\frac{N}{2}}^{i} ( {y}_{1}^{\frac{N}{2}} , {\hat{u}}_{1 , o}^{2 i - 2} ⊕ {\hat{u}}_{1 , e}^{2 i - 2} ) ) + exp ( {LLR}_{\frac{N}{2}}^{i} ( {y}_{\frac{N}{2} + 1}^{N} , {\hat{u}}_{1 , e}^{2 i - 2} ) )} \approx sign ( {LLR}_{\frac{N}{2}}^{i} ( {y}_{1}^{\frac{N}{2}} , {\hat{u}}_{1 , o}^{2 i - 2} ⊕ {\hat{u}}_{1 , e}^{2 i - 2} ) ) s i g n ( {LLR}_{\frac{N}{2}}^{i} ( {y}_{\frac{N}{2} + 1}^{N} , {\hat{u}}_{1 , e}^{2 i - 2} ) ) min ( \vert {LLR}_{\frac{N}{2}}^{i} ( {y}_{1}^{\frac{N}{2}} , {\hat{u}}_{1 , o}^{2 i - 2} ⊕ {\hat{u}}_{1 , e}^{2 i - 2} ) \vert , \vert {LLR}_{\frac{N}{2}}^{i} ( {y}_{\frac{N}{2} + 1}^{N} , {\hat{u}}_{1 , e}^{2 i - 2} ) \vert ) + Ψ ( {LLR}_{\frac{N}{2}}^{i} ( {y}_{i}^{\frac{N}{2}} , {\hat{u}}_{1 , o}^{2 i - 2} ⊕ {\hat{u}}_{1 , e}^{2 i - 2} ) , {LLR}_{\frac{N}{2}}^{i} ( {y}_{\frac{N}{2} + 1}^{N} , {\hat{u}}_{1 , e}^{2 i - 2} ) ) \qquad ( 7 )$$

where y₁^{N} represents a vector (y₁, y₂, . . . , y_{N}), indicating a sequence of N received complex-valued symbols to be decoded. û₁²ⁱ⁻² represents the 1^{st} to the (2i−2)^{th} decoded bits, and LLR_{N}²ⁱ⁻¹(y₁^{N}, û₁²ⁱ⁻²) represents the log-likelihood ratio of the (2i−1)^{th} bit (out of totally N bits) given y₁^{N}, û²ⁱ⁻² and the sequence length N, where

$$i ϵ [ 1 , \frac{N}{2} ] .$$

The definition of the function sign(x) is as follows:

$$sign ( x ) = \{ \begin{matrix}1 , x > 0 \\ 0 , x = 0 \\ - 1 , x < 0\end{matrix} .$$

The definition of the function min(a, b) is as follows:

$$min ( a , b ) = \{ \begin{matrix}b , a \geq b \\ a , a < b\end{matrix} .$$

The symbol ‘⊕’ represents an exclusive OR (also known as modulo-2 sum) operation. The value of LLR_{N}²ⁱ⁻¹(y₁^{N}, û₁²ⁱ⁻²) can be determined in a recursive way based on

$${LLR}_{\frac{N}{2}}^{i} ( {y}_{1}^{\frac{N}{2}} , {\hat{u}}_{1 , o}^{2 i - 2} ⊕ {\hat{u}}_{1 , e}^{2 i - 2} )$$

(equivalent to the first input A) and

$${LLR}_{\frac{N}{2}}^{i} ( {y}_{\frac{N}{2} + 1}^{N} , {\hat{u}}_{1 , e}^{2 i - 2} )$$

(equivalent to the second input B), where û_{1,o}²ⁱ⁻² represents bits with odd indices among the 1^{st} to the (2i−2)^{th} decoded bits and û_{1,e}²ⁱ⁻² represents bits with even indices among the 1^{st} to the (2i−2)^{th} decoded bits. From the above equation (7), it can be seen that, the result of

$$Ψ ( {LLR}_{\frac{N}{2}}^{i} ( {y}_{1}^{\frac{N}{2}} , {\hat{u}}_{1 , o}^{2 i - 2} ⊕ {\hat{u}}_{1 , e}^{2 i - 2} ) , {LLR}_{\frac{N}{2}}^{i} ( {y}_{\frac{N}{2} + 1}^{N} , {\hat{u}}_{1 , e}^{21 - 2} ) )$$

can be determined in accordance with embodiments of the present disclosure.

In addition, a recursive formula used for decoding a bit with an even index (that is, 2i) is shown as below:

$$L L {R}_{N}^{2 i} ( {y}_{1}^{N} , {\hat{u}}_{1}^{2 i - 1} ) = ( 1 - 2 {\hat{u}}_{2 i - 1} ) {LLR}_{\frac{N}{2}}^{i} ( {y}_{1}^{\frac{N}{2}} , {\hat{u}}_{1 , o}^{2 i - 2} ⊕ {\hat{u}}_{1 , e}^{2 i - 2} ) + {LLR}_{\frac{N}{2}}^{i} ( {y}_{\frac{N}{2} + 1}^{N} , {\hat{u}}_{1 , e}^{2 i - 2} ) \qquad ( 8 )$$

where

$$i ϵ [ 1 , \frac{N}{2} ] .$$

The above equations (7) and (8) are calculated recursively all the way to LLR₁ⁱ, which denotes the channel LLRs generated directly from the soft de-mapper.

After the recursion of LLR calculations is complete, LLR_{N}²ⁱ⁻¹(y₁^{N}, û₁²ⁱ⁻²) and/or LLR_{N}²ⁱ(y₁^{N}, û₁²ⁱ⁻¹) can be determined, where

$$i ϵ [ 1 , \frac{N}{2} ] .$$

Then, a hard decision can be performed to determine the decoded bit as below:

$$\begin{matrix}{\hat{u}}_{2 i - 1} = \{ \begin{matrix}0 , if {LLR}_{N}^{2 i - 1} ( {y}_{1}^{N} , {\hat{u}}_{1}^{2 i - 2} ) > 0 \\ 1 , if {LLR}_{N}^{2 i - 1} ( {y}_{1}^{N} , {\hat{u}}_{1}^{2 i - 2} ) \leq 0\end{matrix} & ( 9 ) \\ and / or & \\ {\hat{u}}_{2 i} = \{ \begin{matrix}0 , if {LLR}_{N}^{2 i} ( {y}_{1}^{N} , {\hat{u}}_{1}^{2 i - 1} ) > 0 \\ 1 , if {LLR}_{N}^{2 i} ( {y}_{1}^{N} , {\hat{u}}_{1}^{2 i - 1} ) \leq 0\end{matrix} & ( 10 )\end{matrix}$$

In some embodiments, the above method 200 may be applied to LDPC decoding. For example, the term Ψ as shown in the above equation (4) can be added to the existing check node updating rule, thereby achieving significant decoding error improvement whilst minimizing the cost for calculation.

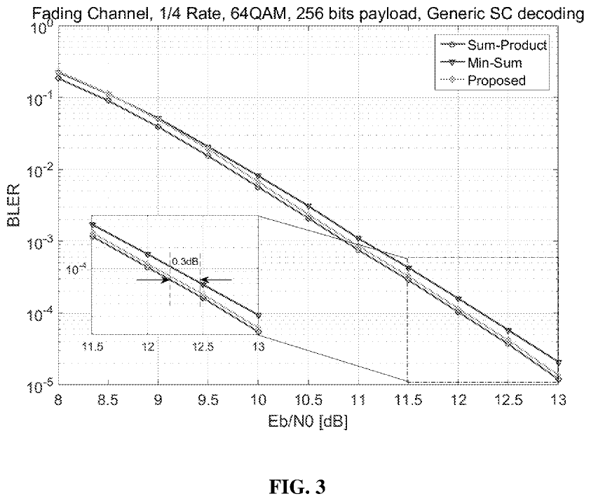

FIG. 3 illustrates a schematic diagram of comparison of three variants of the sum-product operation, labelled as Sum-Product (that is, the optimal decoder using as the performance benchmark), Min-Sum (that is, traditional decoders which ignore operations formulated in the equation (2)) and the proposed solution in accordance with the present disclosure. The URLLC usage scenario is assumed in FIG. 3, in which the payload usually tends to be light and the coding rate is low, for instance, 256 bits transmitted at a rate of ¼. Moreover, the receiving device is generally battery-powered with limited processing capability, and thus the choice of list size is simplified to 1. That is, a generic successive cancellation (SC) algorithm is used for decoding.

It can be seen from FIG. 3 that the curve labelled ‘Sum-Product’ offers the best performance out of the three, since neither simplification nor approximation of any kind is used. In other words, the curve labelled ‘Sum-Product’ represents the direct calculation of the above equation (1). The downside is that the direct calculation of sum-product has prohibitively-high complexity rendering it nearly impossible to be implemented in commercial products. On the other hand, the curve labelled ‘Min-Sum’ only accounts for the first term of the above equation (1) while the second and third terms are completely ignored in order to save computational resources. Undoubtedly, performance degradation will be inevitable for ‘Min-Sum’. As shown in FIG. 3, the proposed solution is capable of compensating the performance loss caused by Min-Sum, bringing roughly 0.3 dB gain. Owing to the effectiveness of the novel design, the curve representing the proposed solution is close enough to the optimal curve labelled ‘Sum-Product’. Considering that the Polar codes in Rel-15 is 0.8 dB away from the ultimate capacity limit as described above, the 0.3 dB improvement is a remarkable achievement, which is crucial for NR URLLC.

Through the above depiction, it can be seen that embodiments of the present disclosure provide a solution for data processing in channel decoding. This solution can greatly improve the error correcting capabilities of LDPC, Polar and/or RM codes, while offering a good balance between performance improvement and implementation complexity. This solution directly compensates the less significant term of the equation (1) instead of relying on decoder structures, thus it can work well with both iterative and successive decoding algorithms. It is to be understood that this solution is not tailored for LDPC or Polar codes. Rather, it can be incorporated in either a LDPC decoder, a Polar and/or RM decoder or other decoders with minimum modification.

In some embodiments, an apparatus capable of performing the method 200 may comprise means for performing the respective steps of the method 200. The means may be implemented in any suitable form. For example, the means may be implemented in a circuitry or software module.

In some embodiments, the means comprises at least one processor; and at least one memory including computer program code, the at least one memory and computer program code configured to, with the at least one processor, cause the performance of the apparatus.

In some embodiments, the apparatus capable of performing the method 200 comprises: means for obtaining, from a channel decoding process, a first input and a second input on which a sum-product operation is to be performed, the sum-product operation including one or more sub-operations; means for determining a set of mapping relationships for approximating at least one of the one or more sub-operations; means for determining, based on the first input, the second input and the set of mapping relationships, a first result of the sum-product operation performed on the first input and the second input; and means for continuing the channel decoding process based on the first result.

In some embodiments, the means for determining the first result comprises: means for determining, based on the first input, the second input and the set of mapping relationships, a second result of the one or more sub-operations; and means for determining the first result at least based on the second result.

In some embodiments, the means for determining the second result comprises: means for determining a first absolute value of a sum of the first input and the second input; means for determining, based on the first absolute value and the set of mapping relationships, a first candidate result of the one or more sub-operations; means for determining a second absolute value of a difference between the first input and the second input; means for determining, based on the second absolute value and the set of mapping relationships, a second candidate result of the one or more sub-operations; and means for selecting, by comparing the first absolute value and the second absolute value, one of the first candidate result, the second candidate result and a predetermined value (such as, 0) as the second result.

In some embodiments, the first input indicates a first ratio between a first likelihood that a first received bit is decoded to a first value and a second likelihood that the first received bit is decoded to a second value. In some embodiments, the second input indicates a second ratio between a third likelihood that a second received bit is decoded to the first value and a fourth likelihood that the second received bit is decoded to the second value.

In some embodiments, the set of mapping relationships are stored as a lookup table in a memory. The means for determining the set of mapping relationships comprises: means for obtaining, from the memory, the lookup table representing the set of mapping relationships.

In some embodiments, the channel decoding process is used for decoding Low Density Parity Check (LDPC) codes.

In some embodiments, the channel decoding process is used for decoding Polar and/or Reed-Muller codes.

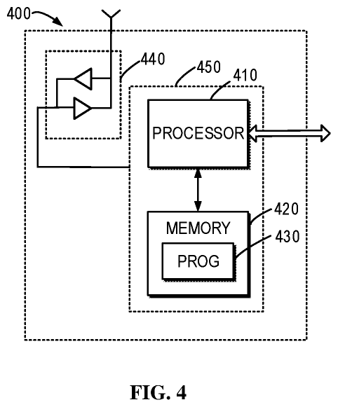

FIG. 4 is a simplified block diagram of a device 400 that is suitable for implementing embodiments of the present disclosure. The device 400 may be used to implement the transmitting device 120 or the receiving device 130 in the embodiments of the present disclosure, for example the network device 101 or the terminal device as shown in FIG. 1, such as the terminal device 111 or 112 as shown in FIG. 1.

As shown, the device 400 includes a processor 410, a memory 420 coupled to the processor 410, a suitable transmitter (TX) and receiver (RX) 440 coupled to the processor 410, and a communication interface coupled to the TX/RX 440. The memory 420 stores at least a part of a program 430. The TX/RX 440 is for bidirectional communications. The TX/RX 440 has at least one antenna to facilitate communication, though in practice an Access Node mentioned in this application may have several ones. The communication interface may represent any interface that is necessary for communication with other network elements.

The program 430 is assumed to include program instructions that, when executed by the associated processor 410, enable the device 400 to operate in accordance with the implementations of the present disclosure, as discussed herein with reference to FIGS. 1 to 3. The implementations herein may be implemented by computer software executable by the processor 410 of the device 400, or by hardware, or by a combination of software and hardware. The processor 410 may be configured to implement various implementations of the present disclosure. Furthermore, a combination of the processor 410 and memory 420 may form processing means 450 adapted to implement various implementations of the present disclosure.

The memory 420 may be of any type suitable to the local technical network and may be implemented using any suitable data storage technology, such as a non-transitory computer readable storage medium, semiconductor based memory devices, magnetic memory devices and systems, optical memory devices and systems, fixed memory and removable memory, as non-limiting examples. While only one memory 420 is shown in the device 400, there may be several physically distinct memory modules in the device 400. The processor 410 may be of any type suitable to the local technical network, and may include one or more of general purpose computers, special purpose computers, microprocessors, digital signal processors (DSPs) and processors based on multicore processor architecture, as non-limiting examples. The device 400 may have multiple processors, such as an application specific integrated circuit chip that is slaved in time to a clock which synchronizes the main processor.

The components included in the apparatuses and/or devices of the present disclosure may be implemented in various manners, including software, hardware, firmware, or any combination thereof. In one embodiment, one or more units may be implemented using software and/or firmware, for example, machine-executable instructions stored on the storage medium. In addition to or instead of machine-executable instructions, parts or all of the units in the apparatuses and/or devices may be implemented, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), and the like.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device. While various aspects of embodiments of the present disclosure are illustrated and described as block diagrams, flowcharts, or using some other pictorial representations, it is to be understood that the block, apparatus, system, technique or method described herein may be implemented in, as non-limiting examples, hardware, software, firmware, special purpose circuits or logic, general purpose hardware or controller or other computing devices, or some combination thereof.

The present disclosure also provides at least one computer program product tangibly stored on a non-transitory computer readable storage medium. The computer program product includes computer-executable instructions, such as those included in program modules, being executed in a device on a target real or virtual processor, to carry out the method 200 as described above with reference to FIG. 2. Generally, program modules include routines, programs, libraries, objects, classes, components, data structures, or the like that perform particular tasks or implement particular abstract data types. The functionality of the program modules may be combined or split between program modules as desired in various embodiments. Machine-executable instructions for program modules may be executed within a local or distributed device. In a distributed device, program modules may be located in both local and remote storage media.

Program code for carrying out methods of the present disclosure may be written in any combination of one or more programming languages. These program codes may be provided to a processor or controller of a general purpose computer, special purpose computer, or other programmable data processing apparatus, such that the program codes, when executed by the processor or controller, cause the functions/operations specified in the flowcharts and/or block diagrams to be implemented. The program code may execute entirely on a machine, partly on the machine, as a stand-alone software package, partly on the machine and partly on a remote machine or entirely on the remote machine or server.

In the context of the present disclosure, the computer program codes or related data may be carried by any suitable carrier to enable the device, apparatus or processor to perform various processes and operations as described above. Examples of the carrier include a signal, computer readable media.

The computer readable medium may be a computer readable signal medium or a computer readable storage medium. A computer readable medium may include but not limited to an electronic, magnetic, optical, electromagnetic, infrared, or semiconductor system, apparatus, or device, or any suitable combination of the foregoing. More specific examples of the computer readable storage medium would include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

For the purpose of the present disclosure as described herein above, it should be noted that,
method steps likely to be implemented as software code portions and being run using a processor at a network element or terminal (as examples of devices, apparatuses and/or modules thereof, or as examples of entities including apparatuses and/or modules therefore), are software code independent and can be specified using any known or future developed programming language as long as the functionality defined by the method steps is preserved;
generally, any method step is suitable to be implemented as software or by hardware without changing the idea of the invention in terms of the functionality implemented;
method steps and/or devices, units or means likely to be implemented as hardware components at the above-defined apparatuses, or any module(s) thereof, (e.g., devices carrying out the functions of the apparatuses according to the embodiments as described above, eNode-B etc. as described above) are hardware independent and can be implemented using any known or future developed hardware technology or any hybrids of these, such as MOS (Metal Oxide Semiconductor), CMOS (Complementary MOS), BiMOS (Bipolar MOS), BiCMOS (Bipolar CMOS), ECL (Emitter Coupled Logic), TTL (Transistor-Transistor Logic), etc., using for example ASIC (Application Specific IC (Integrated Circuit)) components, FPGA (Field-programmable Gate Arrays) components, CPLD (Complex Programmable Logic Device) components or DSP (Digital Signal Processor) components;
devices, units or means (e.g. the above-defined apparatuses, or any one of their respective means) can be implemented as individual devices, units or means, but this does not exclude that they are implemented in a distributed fashion throughout the system, as long as the functionality of the device, unit or means is preserved;
an apparatus may be represented by a semiconductor chip, a chipset, or a (hardware) module comprising such chip or chipset; this, however, does not exclude the possibility that a functionality of an apparatus or module, instead of being hardware implemented, be implemented as software in a (software) module such as a computer program or a computer program product comprising executable software code portions for execution/being run on a processor;
a device may be regarded as an apparatus or as an assembly of more than one apparatus, whether functionally in cooperation with each other or functionally independently of each other but in a same device housing, for example.

It is noted that the embodiments and examples described above are provided for illustrative purposes only and are in no way intended that the present invention is restricted thereto. Rather, it is the intention that all variations and modifications be included which fall within the spirit and scope of the appended claims.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in languages specific to structural features and/or methodological acts, it is to be understood that the present disclosure defined in the appended claims is not necessarily limited to the specific features or acts described above. Rather, the specific features and acts described above are disclosed as example forms of implementing the claims.

Various embodiments of the techniques have been described. In addition to or as an alternative to the above, the following examples are described. The features described in any of the following examples may be utilized with any of the other examples described herein.

1. A device for data processing, comprising:
at least one processor; and
at least one memory including computer program code;
the at least one memory and the computer program codes being configured to, with the at least one processor, cause the device at least to:
obtain, from a channel decoding process, a first input and a second input on which a sum-product operation is to be performed, the sum-product operation including one or more sub-operations;
determine a set of mapping relationships for approximating at least one of the one or more sub-operations;
determine, based on the first input, the second input and the set of mapping relationships, a first result of the sum-product operation performed on the first input and the second input; and
continue the channel decoding process based on the first result.

2. The device of claim 1, wherein the at least one memory and the computer program code are further configured to, with the at least one processor, cause the device to:
determine, based on the first input, the second input and the set of mapping relationships, a second result of the one or more sub-operations; and
determine the first result at least based on the second result.

3. The device of claim 1, wherein the at least one memory and the computer program code are further configured to, with the at least one processor, cause the device to:
determine a first absolute value of a sum of the first input and the second input;
determine, based on the first absolute value and the set of mapping relationships, a first candidate result of the one or more sub-operations;
determine a second absolute value of a difference between the first input and the second input;
determine, based on the second absolute value and the set of mapping relationships, a second candidate result of the one or more sub-operations; and
select, by comparing the first absolute value and the second absolute value, one of the first candidate result, the second candidate result and a predetermined value as the second result.

4. The device of claim 1, wherein the first input indicates a first ratio between a first likelihood that a first received bit is decoded to a first value and a second likelihood that the first received bit is decoded to a second value, and
wherein the second input indicates a second ratio between a third likelihood that a second received bit is decoded to the first value and a fourth likelihood that the second received bit is decoded to the second value.

5. The device of claim 1, wherein the set of mapping relationships are stored as a lookup table in a memory, and wherein the at least one memory and the computer program code are further configured to, with the at least one processor, cause the device to:
obtain, from the memory, the lookup table representing the set of mapping relationships.

6. The device of claim 1 wherein the channel decoding process is used for decoding Low Density Parity Check (LDPC) codes.

7. The device of claim 1 wherein the channel decoding process is used for decoding Polar or Reed-Muller codes.

8. A method of data processing, comprising:
obtaining, from a channel decoding process, a first input and a second input on which a sum-product operation is to be performed, the sum-product operation including one or more sub-operations;
determining a set of mapping relationships for approximating at least one of the one or more sub-operations;
determining, based on the first input, the second input and the set of mapping relationships, a first result of the sum-product operation performed on the first input and the second input; and
continuing the channel decoding process based on the first result.

9. The method of claim 8, wherein determining the first result comprises:
determining, based on the first input, the second input and the set of mapping relationships, a second result of the one or more sub-operations; and
determining the first result at least based on the second result.

10. The method of claim 8, wherein determining the second result comprises:
determining a first absolute value of a sum of the first input and the second input;
determining, based on the first absolute value and the set of mapping relationships, a first candidate result of the one or more sub-operations;
determining a second absolute value of a difference between the first input and the second input;
determining, based on the second absolute value and the set of mapping relationships, a second candidate result of the one or more sub-operations; and
selecting, by comparing the first absolute value and the second absolute value, one of the first candidate result, the second candidate result and a predetermined value as the second result.

11. The method of claim 8, wherein the first input indicates a first ratio between a first likelihood that a first received bit is decoded to a first value and a second likelihood that the first received bit is decoded to a second value, and
wherein the second input indicates a second ratio between a third likelihood that a second received bit is decoded to the first value and a fourth likelihood that the second received bit is decoded to the second value.

12. The method of claim 8, wherein the set of mapping relationships are stored as a lookup table in a memory, and wherein determining the set of mapping relationships comprises:
obtaining, from the memory, the lookup table representing the set of mapping relationships.

13. The method of claim 8, wherein the channel decoding process is used for decoding Low Density Parity Check (LDPC) codes.

14. The method of claim 8, wherein the channel decoding process is used for decoding Polar or Reed-Muller codes.

15. (canceled)

16. (canceled)

17. A computer program embodied on a non-transitory computer-readable storage medium, said computer program comprising program instructions which, when executed by a processor of a device, cause the device to:
obtain, from a channel decoding process, a first input and a second input on which a sum-product operation is to be performed, the sum-product operation including one or more sub-operations;
determine a set of mapping relationships for approximating at least one of the one or more sub-operations;
determine, based on the first input, the second input and the set of mapping relationships, a first result of the sum-product operation performed on the first input and the second input; and
continue the channel decoding process based on the first result.

18. The computer program of claim 17, wherein the program instructions further cause the device to:
determine, based on the first input, the second input and the set of mapping relationships, a second result of the one or more sub-operations; and
determine the first result at least based on the second result.

19. The computer program of claim 17, wherein the program instructions further cause the device to:
determine a first absolute value of a sum of the first input and the second input;
determine, based on the first absolute value and the set of mapping relationships, a first candidate result of the one or more sub-operations;
determine a second absolute value of a difference between the first input and the second input;
determine, based on the second absolute value and the set of mapping relationships, a second candidate result of the one or more sub-operations; and
select, by comparing the first absolute value and the second absolute value, one of the first candidate result, the second candidate result and a predetermined value as the second result.

20. The computer program of claim 17, wherein the first input indicates a first ratio between a first likelihood that a first received bit is decoded to a first value and a second likelihood that the first received bit is decoded to a second value, and
wherein the second input indicates a second ratio between a third likelihood that a second received bit is decoded to the first value and a fourth likelihood that the second received bit is decoded to the second value.

21. The computer program of claim 17, wherein the set of mapping relationships are stored as a lookup table in a memory, and wherein the computer program instructions are further configured to cause the device to:
obtain, from the memory, the lookup table representing the set of mapping relationships.

22. The device of claim 17, wherein the channel decoding process is used for decoding Low Density Parity Check (LDPC) codes
